(19) United States
(12) Patent Application Publication
(10) Pub. No.: US 2026/0320957 A1
(43) Pub. Date: Oct. 15, 2026

(54) MAPPING APPARATUS

(71) Applicant: Sinfonia Technology Co., Ltd., Tokyo (JP)

(72) Inventors: Keigo Sato, Tokyo (JP); Katsumi Yasuda, Tokyo (JP)

(73) Assignee: Sinfonia Technology Co., Ltd., Tokyo (JP)

(21) Appl. No.: 19/689,951

(22) Filed: May 27, 2026

Related U.S. Application Data
(63) Continuation of application No. PCT/JP2024/040375, filed on Nov. 13, 2024.

(30) Foreign Application Priority Data
Nov. 28, 2023 (JP) 2023-200845

(51) Int. Cl. G06V 10/141; G06V 10/60

(52) U.S. Cl. CPC G06V 10/141; G06V 10/60

(57) ABSTRACT

A mapping apparatus for detecting accommodation state of a substrate accommodated in a container having an opening on a side surface thereof, includes: a light emitter configured to emit light toward at least an interior of the container; and an imager configured to sense reflected light emitted from the light emitter and reflected toward the opening by at least the substrate and to image an imaging region including a predetermined detection target point set in advance to detect the substrate, wherein the imager is arranged such that when imaging the imaging region, a virtual straight line passing through a predetermined light receiving point, which is determined in advance by a light receiver of the imager configured to receive the reflected light, and the detection target point intersects with a non-opposing surface, which is different from an opposing surface facing the opening, among inner wall surfaces of the container.

### CROSS-REFERENCE TO RELATED APPLICATION

This application is a Bypass Continuation Application of PCT International Application No. PCT/JP2024/040375, filed on Nov. 13, 2024 and designating the United States, the international application being based upon and claiming the benefit of priority from Japanese Patent Application No. 2023-200845, filed on Nov. 28, 2023, the entire contents of which are incorporated herein by reference.

### TECHNICAL FIELD

The present disclosure relates to a mapping apparatus.

### BACKGROUND

Patent Document 1 discloses a load port (mapping device) equipped with a mapping sensor (detection part). The detection part is configured to be capable of detecting an accommodation state of a plurality of semiconductor wafers (substrates) arranged vertically in a container having an opening on one side surface. More specifically, the detection part includes a light emitting part and an imaging part respectively arranged near the opening. The light emitted from the light emitting part and reflected by the substrates is detected by the imaging part. Thus, an image for determining the accommodation state of each substrate is acquired.

In this case, if the reflected light from the container is strong and is detected by the imaging part, it may be difficult to distinguish this reflected light from the light reflected by the substrate, potentially leading to erroneous determinations regarding a substrate accommodation state. In particular, the reflected light specularly reflected by the inner wall surface of the container located on the opposite side of the opening across a center of the container (hereinafter referred to as an opposing surface) may be a major cause of erroneous detection. Therefore, the detection of such reflected light is suppressed by tilting an imaging axis of the imaging part to the opposite side of an optical axis of the light emitting part.

### PRIOR ART DOCUMENT

### Patent Document

Patent Document 1: Japanese U.S. Pat. No. 7,346,839

### SUMMARY

Even with the above configuration applied to the detection part, if the strong reflected light from the opposing surface is directed toward the imaging part, the strong reflected light will be detected by the imaging part. Therefore, there is still a risk of erroneously determining the substrate accommodation state. However, it is not practical to apply anti-reflective treatment to the opposing surfaces of all already-distributed containers.

The present disclosure intends to reliably suppress erroneous determinations regarding an accommodation state of a substrate through simple means.
According a first invention, a mapping apparatus for detecting an accommodation state of a substrate accommodated in a container having an opening on a side surface thereof, includes: a light emitter configured to emit light toward at least an interior of the container; and an imager configured to sense reflected light emitted from the light emitter and reflected toward the opening by at least the substrate and to image an imaging region including a predetermined detection target point set in advance to detect the substrate, wherein the imager is arranged such that when imaging the imaging region, a virtual straight line passing through a predetermined light receiving point, which is determined in advance by a light receiver of the imager configured to receive the reflected light, and the detection target point intersects with a non-opposing surface, which is a surface different from an opposing surface facing the opening, among inner wall surfaces of the container.
With this arrangement of the imager, the imaging of the opposing surface as a background at the detection target point and in the region in the vicinity thereof can be avoided as much as possible. Therefore, influence of reflected light from the opposing surface can be suppressed as much as possible. In addition, the reflected light emitted from the light emitter and reflected by the non-opposing surface is less likely to reach the imager directly compared to the reflected light from the opposing surface. Therefore, occurrence of erroneous determinations regarding the accommodation state of the substrate at the detection target point can be avoided as much as possible. Therefore, erroneous determinations regarding the accommodation state of the substrate can be suppressed more reliably by simple means.

According to a second invention, the mapping apparatus of the first invention further includes: a determiner configured to determine the accommodation state of the substrate by using determination information included in imaging information, which is information obtained by imaging the imaging region with the imager, wherein the determiner uses, as the determination information, non-opposing surface-containing information which does not include information about a region relating to the opposing surface in the imaging region but includes information about a region relating to both the non-opposing surface and the detection target point in the imaging region.
According to the present disclosure, the information on the region imaged by using the opposing surface as a background in the imaging region can be excluded from the target of the determination performed by the determiner. Therefore, erroneous determinations regarding the accommodation state of the substrate can be effectively suppressed.

According to a third invention, in the mapping apparatus of the first invention or the second invention, the imager images a region including a plurality of detection target points relating to the substrate.
In a configuration in which determinations are required for the plurality of detection target points for a certain substrate, if even one erroneous determination occurs, erroneous determination will occur for all substrates. Accordingly, the present disclosure, which can more reliably suppress erroneous determination, is particularly effective in such a configuration.

According to a fourth invention, in the mapping apparatus of the third invention, the imager includes: a first camera configured to be capable of imaging a first imaging region including two or more detection target points among the plurality of detection target points; and a second camera provided separately from the first camera and configured to be capable of imaging a second imaging region including a detection target point other than the two or more detection target points among the plurality of detection target points to detect a thickness of the substrate.
According to the present disclosure, a so-called cross state (see embodiments for details thereof) can be determined by at least the first camera. In addition, a so-called double state (see embodiment for details thereof) can be determined by the second camera. Accordingly, the accommodation state of the substrate can be determined in more detail.

According to a fifth invention, in the mapping apparatus of the first invention or the second invention, the imager is configured to be capable of imaging at least an end surface of the substrate, wherein the non-opposing surface is a side surface different from the opposing surface.
Depending on material of the substrate, light may be irradiated toward the substrate from obliquely above or obliquely below. However, in general, among the light reflected by the substrate, the light reflected by the end surface is stronger than the light reflected by portions other than the end surface. Therefore, in order to more reliably detect the reflected light from the substrate, it is preferable that the imager be configured to image at least the end surface of the substrate as in the present disclosure. In this case, the side surface among the inner wall surfaces of the container can be imaged by the imager. The reflected light reflected by the side surface other than the opposing surface and traveling directly toward the imager is significantly weaker than the reflected light travelling directly from the opposing surface to the imager. This makes it possible to effectively suppress occurrence of erroneous determination regarding presence or absence of the substrate at the detection target point.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic plan view of an EFEM equipped with a load port according to the present embodiment and its surroundings.

FIG. 2 is a right side view of the load port.

FIG. 3 is a diagram schematically showing a positional relationship between a substrate and a camera.

FIGS. 4A and 4B are diagrams showing an operation of the load port.

FIGS. 5A and 5B are diagrams showing an operation of the load port.

FIG. 6 is a diagram showing an imaging region imaged by a camera.

FIG. 7 is a flowchart showing an overall mapping process.

FIG. 8 is a flowchart showing a determination process for each substrate.

FIGS. 9A to 9D are diagrams explaining determination of accommodation states of substrates.

FIGS. 10A to 10F are diagrams explaining determination of accommodation states of substrates in a modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

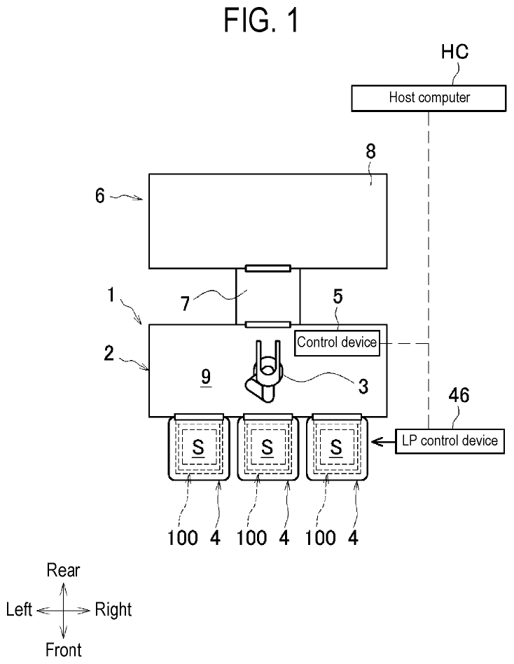

An embodiment of the present disclosure will be described. For ease of description, directions shown in FIG. 1 are defined as front-rear and left-right directions. More specifically, a direction in which the EFEM 1 (described later) and a processing apparatus 6 (described later) are arranged is defined as the front-rear direction (a predetermined direction). In the front-rear direction, a side near the EFEM 1 is defined as a front side. In the front-rear direction, a side near the processing apparatus 6 is defined as a rear side. A direction in which multiple load ports 4 are arranged, which is orthogonal to the front-rear direction, is defined as the left-right direction. A direction orthogonal to both the front-rear direction and the left-right direction is defined as an up-down direction. The up-down direction is a direction parallel to a vertical direction in which gravity acts.

### Overall Configuration of Load Port and its Surrounding

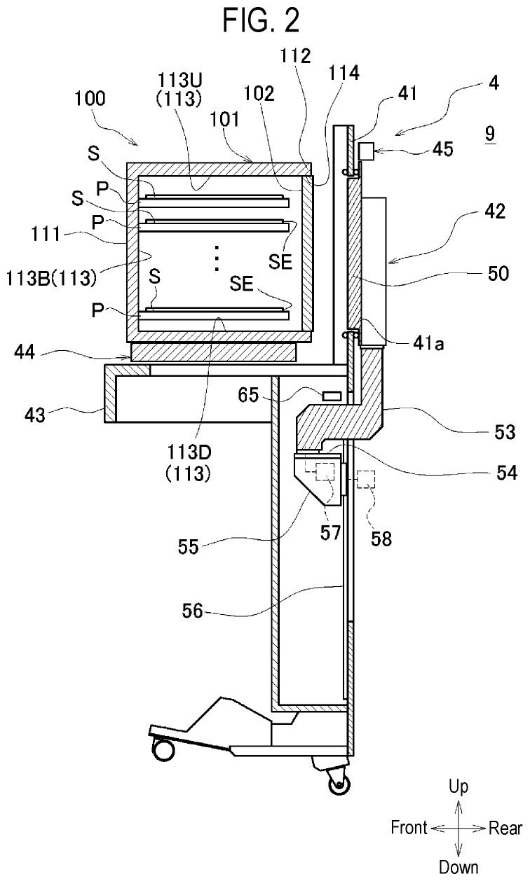

A schematic configuration of the load port 4 (the mapping apparatus of the present disclosure) according to the present embodiment and its surroundings will be described with reference to FIG. 1. FIG. 1 is a schematic diagram of an EFEM 1 equipped with multiple load ports 4 and its surroundings. The “EFEM” is an abbreviation for “Equipment Front End Module.” The EFEM 1 is a device configured to transfer a substrate S between a below-described FOUP 100 (a container in the present disclosure) mounted on each load port 4 and a processing apparatus 6. For example, a semiconductor circuit (not shown) is formed on the substrate S. Examples of types of the substrate S include well-known semiconductor substrates (including wafers), glass substrates, and glass epoxy substrates. The substrate S is, for example, approximately rectangular when viewed in the up-down direction. The substrate S has an end surface SE (see FIG. 2) extending, for example, along the up-down direction.

As shown in FIG. 1, the EFEM 1 includes a housing 2, a transfer robot 3, a plurality of load ports 4, and a control device 5. A processing apparatus 6 is disposed on a rear side of the EFEM 1.

The EFEM 1 is installed at a predetermined position in, for example, a semiconductor factory. The EFEM 1 transfers the substrate S between the FOUP 100 mounted on the load port 4 and the processing apparatus 6 by using the transfer robot 3 arranged in a transfer space 9 in the housing 2. The “FOUP” is an abbreviation for “Front-Opening Unified Pod.” The FOUP 100 is a container capable of accommodating a plurality of substrates S arranged in the up-down direction. The FOUP 100 is transferred by, for example, a FOUP transfer device (not shown). The FOUP 100 is transferred between the FOUP transfer device and the load port 4.

The housing 2 is a box-shaped member having a transfer space 9 in which the substrate S is transferred. The transfer space 9 is separated from a space outside the housing 2 (an external space). The plurality of load ports 4 are connected to the front end of the housing 2. A load lock chamber 7 of the processing apparatus 6 is connected to the rear end of the housing 2. The transfer robot 3 transfers the substrate S between the FOUP 100 and the load lock chamber 7.

The plurality of load ports 4 are arranged, for example, in the left-right direction. The plurality of load ports 4 are attached to the front end of the housing 2. Each load port 4 is configured such that the FOUP 100 is mounted thereon. Each load port 4 is configured to attach and detach a lid 102 (see FIG. 2) to and from a FOUP body 101 (see FIG. 2) of the FOUP 100. Each load port 4 is configured to be capable of performing mapping of a plurality of substrates S accommodated in the FOUP body 101.

The control device 5 is electrically connected to a control part (not shown) of the transfer robot 3, a load port (LP) control device 46 (described later) of the load port 4, and a control part (not shown) of the processing apparatus 6. The control device 5 is configured to communicate with these control parts. The control device 5 may be electrically connected to a host computer HC.

The processing apparatus 6 is an apparatus that performs a predetermined process, such as sputtering, dry etching, or the like, on the substrate S. The processing apparatus 6 includes, for example, a load lock chamber 7 configured to allow the substrate S to temporarily stand by therein, and a processing chamber 8 configured to perform predetermined processes on the substrate S.

### Load Port

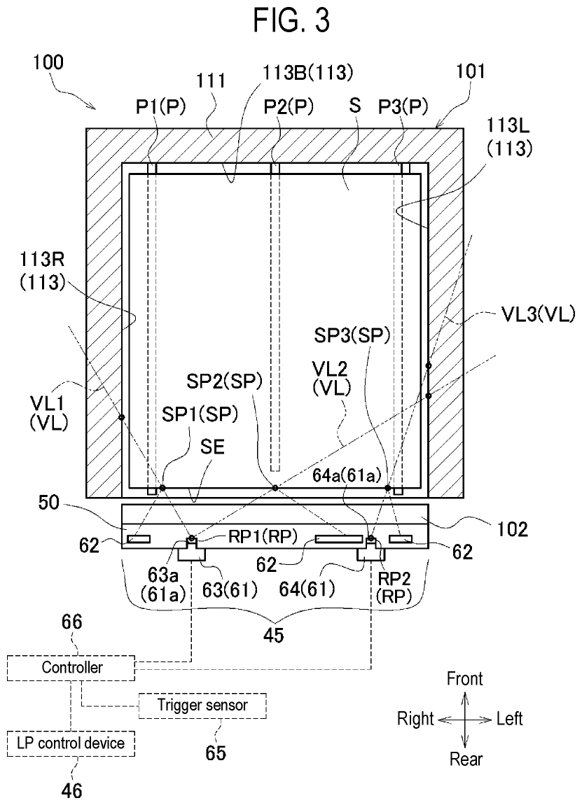

The configuration of the load port 4 will be described with reference to FIGS. 2 and 3. FIG. 2 is a right side view of the load port 4. FIG. 3 is a diagram schematically showing a positional relationship between the substrate S and a plurality of cameras 61 described below (the positional relationship will be described later).

The load port 4 is configured to remove the lid 102 of the FOUP 100 from the FOUP body 101 and to perform mapping of the plurality of substrates S accommodated in the FOUP body 101. As shown in FIG. 2, the load port 4 includes, for example, a base 41, a door mechanism 42, a support frame 43, a mounting part 44, a scanner part 45, and an LP control device 46 (see FIG. 1).

The base 41 is a substantially flat plate-shaped member. The base 41 has a substantially rectangular shape when viewed in the front-rear direction. The base 41 is arranged to extend in the up-down direction. The base 41 is fixed to the EFEM 1. The base 41 is a portion of a partition wall that separates the transfer space 9 from the external space. The base 41 has a substantially rectangular opening 41a. The opening 41a is arranged in an upper portion of the base 41. The opening 41a has a size that allows the lid 102 of the FOUP 100 to pass therethrough in the front-rear direction. The opening 41a is opened and closed by a door body 50 described below.

The door mechanism 42 is configured to be capable of attaching and detaching the lid 102 to and from the FOUP body 101. As shown in FIG. 2, the door mechanism 42 includes, for example, a door body 50, a door support part 53, a guide rail 54, a lifting block 55, a guide rail 56, a motor 57, and a motor 58.

The door body 50 is a plate-like member. When viewed in the front-rear direction, the door body 50 has a substantially rectangular shape. The door body 50 is supported by, for example, the door support part 53. The door body 50 is provided with, for example, an attracting and holding part (not shown) and a latch key (not shown). The attracting and holding part attracts and holds the lid 102 on the front surface of the door body 50. The lid 102 can be fixed to the FOUP body 101 by a locking mechanism (not shown). The locking mechanism is operated by using the latch key to unlock and lock the lid 102 of the FOUP 100.

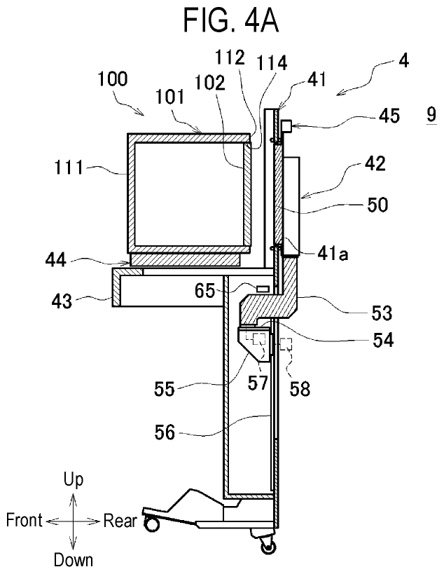

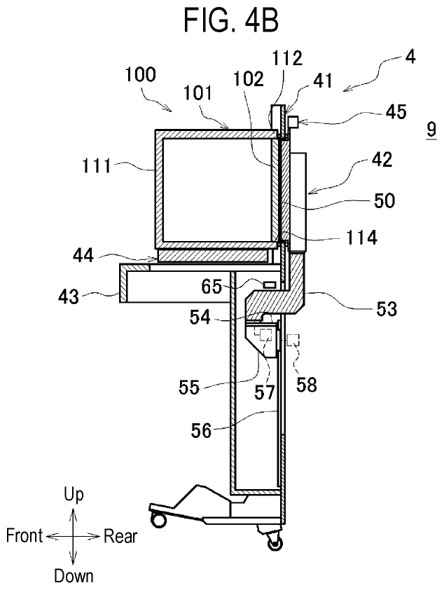

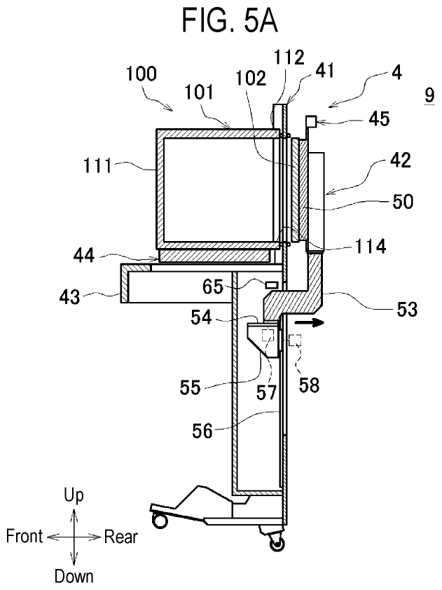

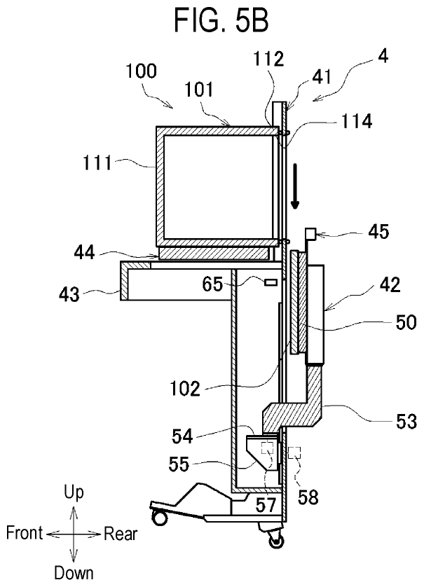

The door support part 53 is a member that supports the door body 50. The door support part 53 is supported by the guide rail 54 so as to be movable in the front-rear direction. The door support part 53 is driven by the motor 57 to move in the front-rear direction. The door support part 53 is moved in the front-rear direction to move the door body 50 between a closed position (see FIG. 4B) and an open position (see FIG. 5A). The closed position is a position of the door body 50 at which the door body 50 closes the opening 41a of the base 41. The open position is a position behind the closed position, and is a position of the door body 50 at which the door body 50 opens the opening 41a. The guide rail 54 is a member that guides the door support part 53 in the front-rear direction. The guide rail 54 is installed on the lifting block 55. The lifting block 55 is a member configured to move the door body 50 in the up-down direction. The lifting block 55 supports the door support part 53 so as to be movable in the front-rear direction. The lifting block 55 is guided in the up-down direction along the guide rail 56. The lifting block 55 is driven by the motor 58 to move in the up-down direction. The lifting block 55 is moved in the up-down direction to move the door body 50 between the above-mentioned open position (see FIG. 5A) and a retracted position (see FIG. 5B) that is lower than the open position. The guide rail 56 is a member that guides the lifting block 55 in the up-down direction. The guide rail 56 is attached to the base 41, for example. The guide rail 56 extends in the up-down direction.

The motor 57 is configured to drive the door support part 53 in the front-rear direction. The motor 57 is, for example, a known stepping motor driven by a pulse signal. The motor 57 is configured to be capable of being controlled by the LP control device 46 to control the position of the door support part 53 in the front-rear direction.

The motor 58 is configured to drive the lifting block 55 to move in the up-down direction. The motor 58 is, for example, a well-known stepping motor driven by a pulse signal. The motor 58 is configured to be capable of controlling the position of the door support part 53 in the up-down direction by being controlled by the LP control device 46.

The support frame 43 is a member configured to support the mounting part 44. The support frame 43 is fixed to the base 41. The support frame 43 is arranged to protrude forward from a middle portion of the base 41 in the up-down direction. The mounting part 44 is a platform-like member on which the FOUP 100 is mounted. The mounting part 44 is supported by the support frame 43. The mounting part 44 is configured to be movable in the front-rear direction with respect to the support frame 43. The mounting part 44 is configured to be movable by a drive mechanism (not shown) between a predetermined delivery position (see FIG. 4A) and a lid opening/closing position (see FIG. 4B) rearward of the delivery position. The delivery position is the position of the mounting part 44 at which the FOUP 100 can be delivered to and from the FOUP transfer device (not shown).

The scanner part 45 is configured to detect the plurality of substrates S in the FOUP 100. The scanner part 45 is arranged in, for example, the transfer space 9. The scanner part 45 may be fixed to, for example, the door body 50. This causes the scanner part 45 to be driven by the motor 58 to move together with the door body 50 in the up-down direction. As shown in FIG. 3, the scanner part 45 includes a plurality of cameras 61, a lighting 62 (a light emitter in the present disclosure), a trigger sensor 65, and a controller 66 (a determiner in the present disclosure).

Each of the plurality of cameras 61 is a device configured to obtain imaging data (imaging information in the present disclosure) of a plurality of substrates S. Each camera 61 is configured and arranged to be capable of imaging a plurality of substrates S at once, for example. The plurality of substrates S referred to herein means, for example, some substrates S among all the substrates S accommodated in the FOUP 100. Alternatively, each camera 61 may image a plurality of substrates S one by one. In addition, in the present embodiment, “imaging” means that an image of an object is recorded (i.e., photographed) by each camera 61. Each camera 61 is configured and arranged to image a part of the substrate S in the left-right direction. Each camera 61 is configured to image at least a part of the end surface SE of the substrate S (more specifically, a rear end surface of the substrate S). The plurality of cameras may be arranged, for example, on the upper side of the door body 50, and arranged in the left-right direction. Each camera 61 is electrically connected to the controller 66. Each camera 61 includes, for example, a light receiving lens 61a (a light receiver in the present disclosure) and an imaging element not shown. The light receiving lens 61a is a light collecting member configured to receive light and focus the same on the imaging element. A surface of the light receiving lens 61a faces, for example, the front side (the FOUP). The imaging element is, for example, a well-known device such as a CCD or the like. The imaging element detects light, converts the light into an electrical signal, and transmits the electrical signal to the controller 66. A combination of a plurality of cameras 61 constitutes the imager in the present disclosure. In other words, in the present embodiment, the imager in the present disclosure includes a plurality of cameras 61.

The lighting 62 is, for example, a device configured to illuminate an interior of the FOUP 100 substantially uniformly in the left-right direction. The lighting 62 includes, for example, a plurality of LED elements (not shown). The plurality of LED elements (not shown) are arranged to form, for example, substantially linear rows extending in the left-right direction. Furthermore, it is preferable that a plurality of such rows of LED elements are arranged in the up-down direction. Alternatively, the lighting 62 may include one or more LED elements (not shown) and a diffuser plate (not shown) arranged in front of the one or more LED elements (on the side of the FOUP 100 in the front-rear direction). With the above configuration, light (irradiated light) having various directional components in the left-right and front-rear directions is irradiated from the lighting 62 toward at least the interior of the FOUP 100. Although a plurality of lightings 62 are shown in FIG. 3, the number of lighting 62 may be one.

A part of the irradiation light emitted from the lighting 62 and traveling forward is reflected backward by the substrate S or an inner wall surfaces 113 described below (reflected light). In particular, the reflected light specularly reflected by the end surface SE (the rear end surface) of the substrate S toward the rear side (the side near the opening in the present disclosure) is used to detect the substrate S. A part of the irradiation light (see dashed lines in FIG. 3) is specularly reflected by the end surface SE and then sensed by one of the plurality of cameras 61. The imaging element of each camera 61 can sense the reflected light to image a portion of the rear end surface of the substrate S in the left-right direction and the background portion thereof, thereby obtaining imaging data. The imaging data obtained by the imaging element is transferred to the controller 66.

The trigger sensor 65 is a sensor used to determine an imaging start timing by the plurality of cameras 61. More specifically, the trigger sensor 65 is configured to be capable of detecting the movement of the door support part 53 when a portion of the door support part 53 moves in the up-down direction. The trigger sensor 65 may be, for example, a known photo interrupter. The photo interrupter includes a light emitter and a light receiver (not shown), and detects the light (transmitted light) emitted from the light emitter by using the light receiver. As shown in FIG. 2, the trigger sensor 65 is arranged, for example, inside the support frame 43 and immediately in front of the base 41. That is, the trigger sensor 65 is located near the door support part 53 when the door body 50 is located at least at the open position, and is configured to be capable of detecting the door support part 53, for example. The door support part 53 includes, for example, a light shielding part (not shown) that can move between a position that blocks the light emitted from the light emitter of the trigger sensor 65 and a position that does not block the light. The trigger sensor 65 may send to the controller 66 a signal (trigger signal) indicating that the door support part 53 has been detected, for example, when the transmitted light is blocked by the light shielding part. The trigger sensor 65 may also send to the controller 66 a signal indicating that the door support part 53 is no longer detected, for example, when it detects the transmitted light that is no longer blocked due to the downward movement of the door support part 53.

The trigger sensor 65 may include, for example, a photo reflector (a reflected light sensor) instead of the photo interrupter. Alternatively, the trigger sensor 65 may not be provided. In this case, the imaging start timing may be determined by the LP control device 46 based on, for example, the number of pulse signals (the number of steps) sent from the LP control device 46 to the motor 58.

The controller 66 is configured to perform a mapping process described below. The controller 66 includes a CPU, a ROM, and a RAM (memory), which are not shown. The controller 66 performs calculations for the mapping process by using the CPU in accordance with a program stored in the ROM. The controller 66 is electrically connected to the LP control device 46, the plurality of cameras 61, and the trigger sensor 65. The controller 66 may include a well-known internal storage, such as a well-known NAND flash memory, an HDD, or an SSD, which are not shown.

The LP control device 46 includes a CPU, a ROM, and a RAM (memory), which are not shown. The LP control device 46 controls each mechanism of the load port 4 by the CPU in accordance with a program stored in the ROM. The LP control device 46 also communicates with the control device 5 of the EFEM 1, the host computer HC, and the like. The LP control device 46 also sends information relating to the mapping process to the controller 66 (described later).

### FOUP

Next, an example of a more specific configuration of the FOUP 100 will be described with reference to FIGS. 2 and 3. The front, rear, left, and right directions shown in FIG. 3 are directions for convenience of explanation when an opening 114, which will be described later, faces the rear side.

The FOUP 100 is a container having a generally rectangular parallelepiped shape. The FOUP 100 is configured to be capable of accommodating a plurality of substrates S arranged in the up-down direction. As shown in FIGS. 2 and 3, the FOUP 100 includes a FOUP body 101 and a lid 102. The FOUP body 101 is a member having a generally rectangular parallelepiped shape. The FOUP body 101 can be supported by the mounting part 44. The FOUP body 101 includes, for example, a wall portion 111, an opening portion 112, and a plurality of poles P.

The wall portion 111 is a substantially rectangular parallelepiped member arranged to surround an internal space of the FOUP 100. The wall portion 111 is formed, for example, by fixing a plurality of substantially flat plate-shaped members such as acryl plates to each other with fixing tools (not shown). The wall portion 111 has a plurality of inner wall surfaces 113 (see FIGS. 2 and 3). The opening portion 112 is arranged, for example, at a rear end (a side surface) of the FOUP body 101. The opening portion 112 has an opening 114 that is substantially rectangular when viewed in the front-rear direction.

Each of the plurality of inner wall surfaces 113 is arranged to face an inside of the FOUP 100. Each inner wall surface 113 is, for example, substantially rectangular. The plurality of inner wall surfaces 113 include a back surface 113B (the opposing surface in the present disclosure), an upper surface 113U (see FIG. 2), a lower surface 113D (see FIG. 2), a left side surface 113L (see FIG. 3), and a right side surface 113R (see FIG. 3). The back surface 113B is the inner wall surface 113 arranged at the frontmost side among the plurality of inner wall surfaces 113. In FIG. 3, the back surface 113B faces the rear side (i.e., the side near the opening 114 in the front-rear direction). The back surface 113B extends in the up-down direction and the left-right direction. The back surface 113B is arranged on the opposite side to the opening 114 across the center of the FOUP body 101 in the front-rear direction. The upper surface 113U is connected to an upper end of the back surface 113B and extends to the rear end of the FOUP body 101 in the front-rear direction. The upper surface 113U faces downward. The lower surface 113D is connected to a lower end of the back surface 113B and extends to the rear end of the FOUP body 101 in the front-rear direction. The lower surface 113D faces upward. The left side surface 113L is connected to a left end of the back surface 113B, the left end of the upper surface 113U, and the left end of the lower surface 113D, respectively, and extends to the rear end of the FOUP body 101 in the front-rear direction. The left side surface 113L faces rightward. The right side surface 113R is connected to a right end of the back surface 113B, a right end of the upper surface 113U, and a right end of the lower surface 113D, respectively, and extends to the rear end of the FOUP body 101 in the front-rear direction. The right side surface 113R faces leftward.

The plurality of poles P are configured to support the plurality of substrates S substantially horizontally. The plurality of poles P are arranged in a substantially rectangular parallelepiped space surrounded by the FOUP body 101. Each of the plurality of poles P is a substantially rod-shaped member extending, for example, along the front-rear direction. Each of the plurality of poles P is fixed, for example, to the back surface 113B. A portion of the substrate S is placed on any of the poles P. As shown in FIG. 2, the plurality of poles P are arranged in the up-down direction so as to correspond to the plurality of substrates S. Furthermore, as shown in FIG. 3, the plurality of poles P are arranged in the left-right direction. In other words, the plurality of poles P include a plurality of first poles P1, a plurality of second poles P2, and a plurality of third poles P3. The plurality of first poles P1 are arranged, for example, immediately to the left of the right side surface 113R, and arranged in the up-down direction. The plurality of second poles P2 are arranged, for example, at a substantially central position in the left-right direction of the FOUP body 101, and arranged in the up-down direction. The plurality of third poles P3 are arranged, for example, near the left side surface 113L, and arranged in the up-down direction. The number of the first poles P1, the number of the second poles P2, and the number of the third poles P3 are the same. One first pole P1, one second pole P2, and one third pole P3 are installed for each substrate S. A set of the first poles P1, the second poles P2, and the third poles P3 are arranged at approximately equal positions in the up-down direction to support one substrate S. A space for supporting one substrate S is called a slot. In other words, the FOUP 100 has a plurality of slots arranged in the up-down direction.

The lid 102 is configured to open and close the opening 114. The lid 102 is attached to and detached from the FOUP body 101 by the load port 4. The lid 102 includes a locking mechanism (not shown) that can change a state of the lid 102 between a state in which the lid 102 is fixed to the FOUP body 101 and a state in which the lid 102 is released from the FOUP body 101. The locking mechanism is unlocked and locked by a latch key (not shown).

### Basic Operation of Load Port

A basic operation of the load port 4 will be described with reference to FIGS. 4A to 5B. FIGS. 4A to 5B are right side views of the load port 4 in operation.

First, the FOUP 100 is mounted on the mounting part 44 (see FIG. 4A). The LP control device 46 moves the mounting part 44 from the delivery position (see FIG. 4A) to the lid opening/closing position (see FIG. 4B). Next, the LP control device 46 causes the lid 102 to be attracted and held by the attracting and holding part of the door body 50 and unlocks the locking mechanism of the lid 102 with the latch key. Furthermore, the LP control device 46 controls the motor 57 to move the door support part 53 rearward (see a rightward arrow in FIG. 5A). As a result, the door body 50 moves from a predetermined closed position (see FIG. 4B) to an open position (see FIG. 5A). As a result, the lid 102 is removed from the FOUP body 101.

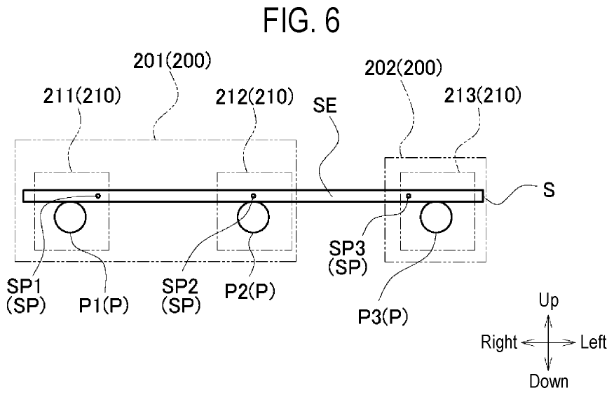

Next, the LP control device 46 controls the motor 58 to move the door body 50 from the open position (see FIG. 5A) to the retracted position (see FIG. 5B). Accordingly, the plurality of cameras 61 of the scanner part 45 are moved downward together with the door body 50. In response to commands from the controller 66, the plurality of cameras 61 image a predetermined imaging region 200 (see FIG. 6), which will be described later, at predetermined positions in the up-down direction, and acquire imaging data. The controller 66 performs a mapping process based on the imaging data acquired by the plurality of cameras 61. The mapping process includes determining the accommodation state of each of the plurality of substrates S. Details of the mapping process will be described later.

After the mapping process is completed, the transfer robot 3 starts transferring the substrates S between the FOUP 100 and the processing apparatus 6. The processing apparatus 6 sequentially performs a predetermined process on some or all of the substrates S. The processed substrates S are returned to the FOUP 100 by the transfer robot 3. After all of the substrates S have been returned to the FOUP 100, the LP control device 46 causes the door mechanism 42 and the like to perform a reverse operation to the operation of opening the lid 102, and mounts the lid 102 on the FOUP body 101. In this manner, a series of processes are performed from when the FOUP 100 is transferred to the load port 4 to when it becomes possible to unload the FOUP 100.

Here, in a case where the reflected light from the inner wall surfaces 113 of the FOUP 100 is strong and this reflected light is detected by the cameras 61, it is difficult to distinguish the reflected light from the light reflected by the substrate S, which may lead to erroneous determinations regarding the accommodation state of the substrate. In particular, the reflected light specularly reflected by the back surface 113B may be a major cause of erroneous determinations. More specifically, since the back surface 113B is approximately perpendicular to the front-rear direction, an angle of incidence of light having a front-rear component in the irradiated light on the back surface 113B is small. As a result, a large amount of light is specularly reflected by the back surface 113B and is directed toward the cameras 61. Consequently, the reflected light from the back surface 113B may be erroneously recognized as the reflected light from the substrate S. Therefore, in order to more reliably suppress erroneous determinations regarding the accommodation state of the substrate S by simple means, the load port 4 has the following configuration. In particular, the plurality of cameras 61 are arranged as follows.

### Detailed Arrangement of Camera, etc.

The detailed arrangement of the cameras 61 will be described with reference to FIGS. 3 and 6. FIG. 3 shows a positional relationship between the plurality of cameras 61 and the FOUP 100 when the plurality of cameras 61 are imaging the substrate S. FIG. 6 is a diagram showing a plurality of imaging regions 200 (a first imaging region 201 and a second imaging region 202). As described above, the scanner part 45 includes the plurality of cameras 61 and the lighting 62. As shown in FIG. 3, the plurality of cameras 61 include, for example, a first camera 63 and a second camera 64.

The first camera 63 is, for example, a low-magnification camera with a large horizontal field of view. Preferably, the horizontal field of view of the first camera 63 is, for example, 100 degrees or more. More specifically, the horizontal field of view is preferably 100 degrees or more and 150 degrees or less. A resolution of the first camera 63 is, for example, 1.2 million pixels. An imaging axis of the first camera 63 is, for example, approximately parallel to the front-rear direction (i.e., approximately horizontal). The horizontal field of view, resolution, and orientation of the imaging axis of the first camera 63 are not limited thereto. As shown in FIG. 3, the first camera 63 is, for example, arranged between the first pole P1 and the second pole P2 in the left-right direction. The first camera 63 is arranged at an appropriate position so that the reflected light specularly reflected from the end surface SE near the first pole P1 and the reflected light specularly reflected from the end surface SE near the second pole P2 travel toward the first camera 63. A distance between the first camera 63 and the first pole P1 in the left-right direction is preferably shorter than, for example, a distance between the first camera 63 and the second pole P2 in the left-right direction. The first camera 63 is configured and arranged to image a first imaging region 201 (see FIG. 6), which is one of the imaging regions 200. As shown in FIG. 6, the first imaging region 201 is longer in the up-down direction than a length obtained by, for example, adding a diameter of the pole P and a thickness of the substrate S. The first imaging region 201 extends in the left-right direction from, for example, a position on the right side of the first pole P1 to a position on the left side of the second pole P2.

Data relating to determination regions 210 (a first determination region 211 and a second determination region 212), which are portions of the first imaging region 201, is used as determination data to determine the accommodation state of the substrate S. The first determination region 211 is a region in the vicinity of the first pole P1. The second determination region 212 is a region in the vicinity of the second pole P2. Hereinafter, for ease of explanation, the determination data relating to the first determination region 211 is referred to as first determination data. The determination data relating to the second determination region 212 is referred to as second determination data. The first and second determination data correspond to the determination information in the present disclosure. In this embodiment, the first and second determination data are collectively referred to as low-magnification data.

The second camera 64 is, for example, a high-magnification camera with a smaller horizontal field of view compared to the first camera 63. The horizontal field of view of the second camera 64 is preferably, for example, 30 degrees or more and 35 degrees or less. It is particularly preferable that the horizontal field of view be 34 degrees or more. A resolution of the second camera 64 is, for example, 1.2 million pixels. An imaging axis of the second camera 64 is, for example, approximately parallel to the front-rear direction (i.e., approximately horizontal). The horizontal field of view, resolution, and orientation of the imaging axis of the second camera 64 are not limited thereto. As shown in FIG. 3, the second camera 64 is arranged between the second pole P2 and the third pole P3 in the left-right direction, for example. The second camera 64 is arranged at an appropriate position so that the reflected light specularly reflected by the end surface SE located near the third pole P3 travels toward the second camera 64. A distance between the second camera 64 and the third pole P3 in the left-right direction is preferably shorter than a distance between the second camera 64 and the second pole P2 in the left-right direction, for example. The second camera 64 is configured and arranged to image the second imaging region 202 (see FIG. 6), which is one of the imaging regions 200. As shown in FIG. 6, the second imaging region 202 is longer in the up-down direction than, for example, the length obtained by adding the diameter of the pole P and the thickness of the substrate S. More specifically, the second imaging region 202 is longer in the up-down direction than, for example, a length obtained by adding the diameter of the pole P and the thickness of two substrates S. The second imaging region 202 extends in the left-right direction, for example, from a position on the right side of the third pole P3 to a position on the left side of the third pole P3.

Data relating to the determination region 210 (a third determination region 213), which is a portion of the second imaging region 202, is used as determination data to determine the accommodation state of the substrate S. The third determination region 213 is a region in the vicinity of the third pole P3. Hereinafter, for convenience of explanation, the determination data relating to the third determination region 213 will be referred to as third determination data. Just like the first and second determination data, the third determination data corresponds to the determination information in the present disclosure. In the present embodiment, the third determination data will also be referred to as high magnification data.

Details of the positions of the respective cameras 61 will be described with reference to FIGS. 3 and 6. As shown in FIG. 3, when the camera 61 images the imaging region 200, the camera 61 focuses the reflected light by using the light receiving lens 61a. In general, principal points (a front principal point and a rear principal point), focal points (a front focal point and a rear focal point), and nodal points (a front nodal point and a rear nodal point) of the lens are determined in advance according to lens specifications. Although not shown in the drawings, in the present embodiment, for example, the front nodal point of the light receiving lens 61a (a center point of the surface of the light receiving lens 61a on the side of the substrate S) is defined as a light receiving point RP for convenience of explanation. The light receiving point RP relating to the first camera 63 is called a first light receiving point RP1. The light receiving point RP relating to the second camera 64 is called a second light receiving point RP2.

Furthermore, as shown in FIG. 6, a predetermined point included in each determination region 210 and included in the end surface SE is called a detection target point SP (see FIGS. 3 and 6) for convenience of explanation. Positions of the detection target point SP in the left-right direction and the front-rear direction are set in advance according to, for example, specifications of the FOUP 100, specifications of the substrate S, arrangement of the lighting 62, configuration and arrangement of the cameras 61, and the like. The detection target point SP included in the first determination region 211 is called a first detection target point SP1. As shown in FIG. 3, the first detection target point SP1 may be located, for example, on the left side of the first pole P1 (i.e., inside the first pole P1 in the left-right direction). The detection target point SP included in the second determination region 212 is called a second detection target point SP2. As shown in FIG. 3, the second detection target point SP2 may be located, for example, at approximately the same position as the center position of the second pole P2 in the left-right direction. The detection target point SP included in the third determination region 213 is called a third detection target point SP3. As shown in FIG. 3, the third detection target point SP3 may be located, for example, on the right side of the third pole P3 (i.e., inside the third pole P3 in the left-right direction). The position of each detection target point SP is not limited to the above. For example, one or more detection target points SP may be set directly above the corresponding pole P.

The first camera 63 images the imaging region 200 (the first imaging region 201) (see FIG. 6) that includes the first detection target point SP1 and the second detection target point SP2. The second camera 64 images the imaging region 200 (the second imaging region 202) (see FIG. 6) that includes the third detection target point SP3. In this way, the plurality of (two) cameras 61 image the region including a plurality of (a total of three) detection target points SP relating to each substrate S.

As shown in FIG. 3, for convenience of explanation, a virtual straight line passing through a predetermined light receiving point RP and a predetermined detection target point SP is called a virtual straight line VL. More specifically, the virtual straight line VL passing through the first light receiving point RP1 and the first detection target point SP1 is called a first virtual straight line VL1. The virtual straight line VL passing through the first light receiving point RP1 and the second detection target point SP2 is called a second virtual straight line VL2. The virtual straight line VL passing through the second light receiving point RP2 and the third detection target point SP3 is called a third virtual straight line VL3. The first virtual straight line VL1 intersects with, for example, the right side surface 113R of the FOUP 100. The second virtual straight line VL2 and the third virtual straight line VL3 intersect with, for example, the left side surface 113L of the FOUP 100. The right side surface 113R and the left side surface 113L are side surfaces among the inner wall surfaces 113 that are different from the back surface 113B (opposing surface). Hereinafter, for the sake of explanation, the right side surface 113R and the left side surface 113L will be generally referred to as non-opposing surfaces.

With this arrangement, each camera 61 can image the region near the detection target point SP (i.e., the determination region 210) by using one of the non-opposing surfaces (and the pole P) as the background. In other words, it is possible to suppress imaging data relating to the back surface 113B from being included in the imaging data relating to each determination region 210 as much as possible. Since the non-opposing surfaces are approximately parallel to the front-rear direction, an amount of irradiated light reflected rearward by the non-opposing surfaces and traveling directly toward the camera 61 is very small compared to an amount of light reflected by the back surface 113B and directed toward the camera 61. Accordingly, it is possible to suppress the light that could cause erroneous detection of the substrate S from being included in the imaging data relating to the determination region 210 as much as possible.

### Mapping Process

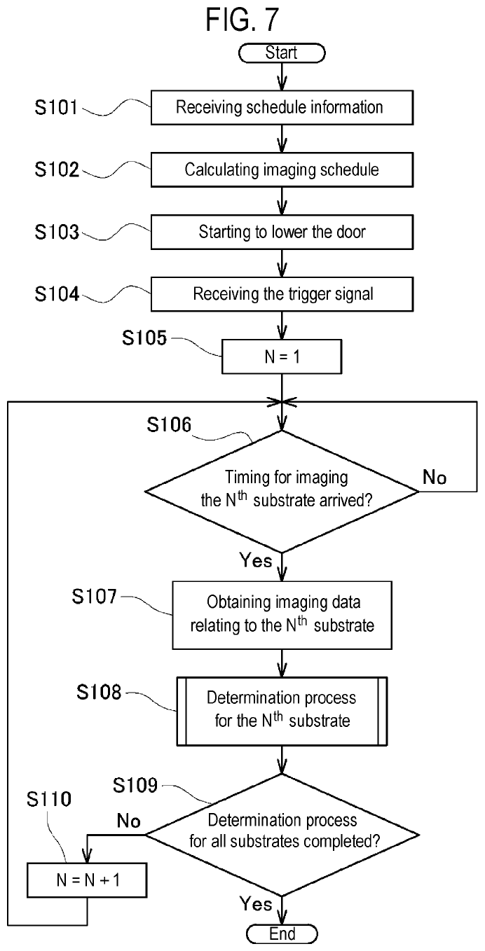

Next, an example of the mapping process executed by the load port 4 will be described mainly with reference to FIG. 7. FIG. 7 is a flowchart showing the entire mapping process.

The initial state is as follows. The FOUP 100 containing a plurality of substrates S is mounted on the mounting part 44. The mounting part 44 is located at the lid opening/closing position. The lid 102 of the FOUP 100 is opened by the door mechanism 42. The door body 50 is located at the open position (see FIG. 5A).

First, the LP control device 46 transmits information (schedule information) relating to a schedule of imaging performed by the camera 61 to the controller 66. The information relating to the schedule of imaging is, for example, the specifications of the FOUP 100, the number of substrates S that can be stored in the FOUP 100, a position of the uppermost slot among the plurality of slots of the FOUP 100, a set value of a descending speed of the door body 50, or the like. The schedule information is, for example, sent in advance to the LP control device 46 from the control part (not shown) of the processing apparatus 6. In addition to the schedule information, for example, a set value for the thickness of the substrate S (information for performing double determination described later) and the like are also sent in advance from the control part of the processing apparatus 6 to the LP control device 46. The controller 66 receives the schedule information from the LP control device 46 (step S101 shown in FIG. 7). The controller 66 calculates an imaging schedule based on the schedule information (step S102). The imaging schedule is a schedule of a timing at which the cameras 61 are caused to perform imaging when a certain amount of time has elapsed after the controller 66 receives a predetermined trigger signal.

Next, the LP control device 46 controls the motor 58 of the door mechanism 42 to start lowering the scanner part 45 together with the door body 50 (and the door support part 53) (step S103). At this time, the trigger sensor 65 detects the start of movement of the door support part 53 and sends a detection signal to the controller 66. The controller 66 receives the detection signal as the trigger signal (step S104). Then, the controller 66 causes each camera 61 to perform imaging based on the imaging schedule, for example, in the following procedure.

The controller 66 sets, to an initial value, a counter configured to count (determine) the substrates S accommodated in the FOUP 100 one by one sequentially from top. More specifically, the controller 66 inputs, for example, 1 to a predetermined variable N (step S105).

Next, the controller 66 determines whether or not a timing for imaging the N^{th} substrate S has arrived based on the imaging schedule (step S106). When the timing for imaging the N^{th} substrate S has not arrived (step S106: No), the scanner part 45 continues to be lowered by the LP control device 46. When the timing for imaging the N^{th} substrate S has arrived (step S106: Yes), the controller 66 controls the plurality of cameras 61 to image the imaging region 200 relating to the N^{th} substrate S and obtains imaging data relating to the substrate S (step S107). More specifically, the controller 66 causes the first camera 63 to image the first imaging region 201 and the second camera 64 to image the second imaging region 202. The controller 66 temporarily stores the imaging data obtained by these cameras 61 in, for example, a memory. The controller 66 may further cause the imaging data to be stored in, for example, the above-mentioned internal storage (not shown).

Next, the controller 66 determines the accommodation state of the N^{th} substrate S based on the determination data included in the imaging data (determination process, step S108). Details will be described later.

Next, the controller 66 determines whether the determination process for all the substrates S has been completed (step S109). If the controller 66 determines that there is any substrate S that has not yet been subjected to the determination process (step S109: No), the controller 66, for example, adds 1 to the variable N (step S110), and returns to step S106. When the determination process for all the substrates S has been completed (step S109: Yes), the controller 66 terminates the mapping process.

### Determination Process

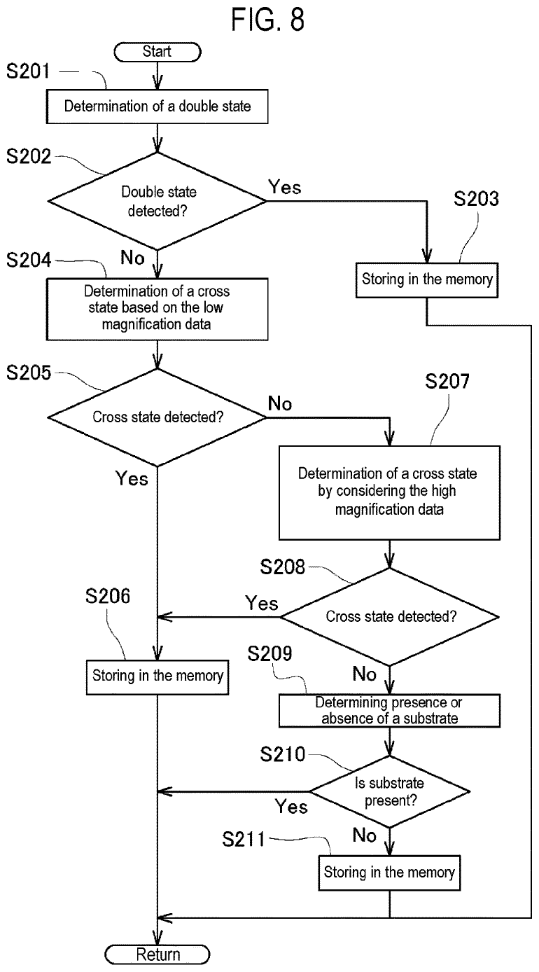

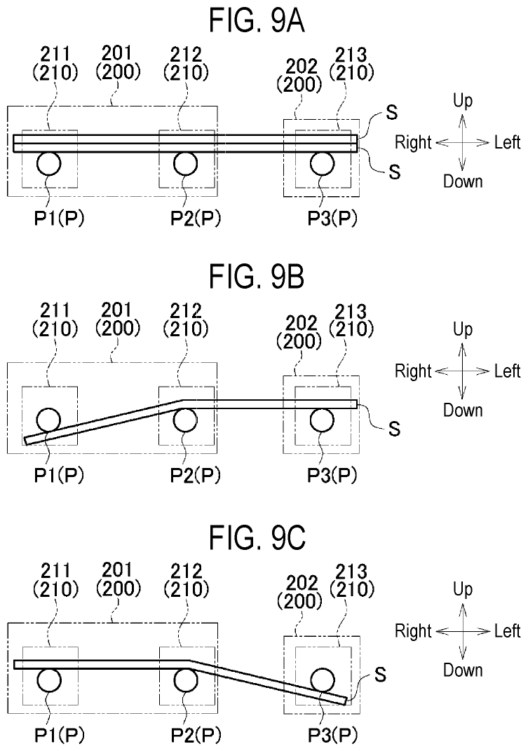

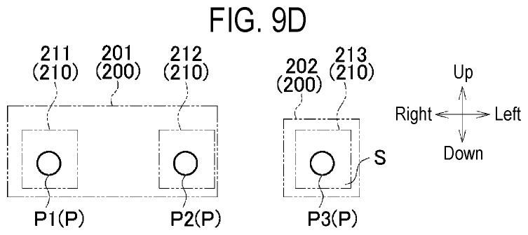

An example of the determination process for the accommodation state of each substrate S will be described with reference to FIGS. 8 to 9D. FIG. 8 is a flowchart showing the determination process for each substrate S. FIGS. 9A to 9D are diagrams for explaining the determination of the accommodation state of the substrate S. In summary, the controller 66 determines whether the accommodation state of the N^{th} substrate S is a double state or a cross state, whether the N^{th} substrate S is not present, or whether the N^{th} substrate S is accommodated normally.

In the following determination process, the controller 66 uses non-opposing surface-containing data (non-opposing surface-containing information in the present disclosure) as determination data. The non-opposing surface-containing data is data that does not include data of a region relating to the back surface 113B in the imaging region 200, but includes data of a region relating to both the non-opposing surfaces and the detection target point SP. In other words, the controller 66 uses, as the determination data, data relating to the determination region 210 in which the back surface 113B is not imaged as the background and the left side surface 113L or the right side surface 113R is imaged as the background.

First, the controller 66 determines whether the accommodation state of the N^{th} substrate S is a double state or not (double determination; step S201 shown in FIG. 8). The double state is a state in which two (or more) substrates S are accommodated vertically overlappingly in one slot as shown in FIG. 9A. The controller 66 detects the thickness of the N^{th} substrate S based on, for example, the third determination data. In a case where the detected thickness exceeds the set value for the thickness of one substrate S, the controller 66 determines that the accommodation state of the N^{th} substrate S is in the double state (i.e., a double state is detected). In a case where the detected thickness is approximately the same as the set value for the thickness of one substrate S, the controller 66 determines that the N^{th} substrate S is not in a double state.

When the double state is detected (step S202: Yes), the controller 66 stores information indicating that the accommodation state of the N^{th} substrate S is a double state in the memory (step S203). Then, the controller 66 terminates the determinations regarding the N^{th} substrate S.

When the double state is not detected (step S202: No), the controller 66 determines whether or not the accommodation state of the N^{th} substrate S is a cross state (cross determination). The cross state is a state in which a portion of the substrate S is placed on a part of a set of poles P arranged in the left-right direction, and another portion of the substrate S is located below the set of poles P as shown in FIG. 9B or 9C, for example.

As a procedure for the cross determination, first, the controller 66 determines whether the accommodation state of the N^{th} substrate S is a cross state based on, for example, low magnification data (step S204). More specifically, the controller 66 compares an up-down direction position of the substrate S detected based on the first determination data (hereinafter referred to as a first substrate position) with an up-down direction set position of the first pole P1 corresponding to the substrate S (hereinafter referred to as a first set position). The set position of each pole P in the up-down direction is pre-stored in the memory of the controller 66. Since a design tolerance is allowed for the position of each pole P, there may be a difference between a design position and an actual position of each pole P in the up-down direction. In this case, the controller 66 may detect the actual position of each pole P, for example, by pattern matching. For example, when the first substrate position is lower than the first set position, the controller 66 determines that the accommodation state of the N^{th} substrate S is a cross state (i.e., a cross state is detected).

The controller 66 also compares an up-down direction position of the substrate S detected based on the second determination data (hereinafter referred to as a second substrate position) with an up-down direction set position of the second pole P2 corresponding to the substrate S (hereinafter referred to as a second set position). The second set position may be set, for example, as a common position with the first set position in the up-down direction, or may be set independently of the first set position. For example, when the second substrate position is lower than the second set position, the controller 66 determines that the accommodation state of the N^{th} substrate S is a cross state (i.e., the cross state is detected). When the cross state is detected (step S205: Yes), the controller 66 stores information indicating that the accommodation state of the N^{th} substrate S is a cross state in the memory (step S206). Then, the controller 66 terminates the determinations regarding the N^{th} substrate S.

When the cross state is not detected based on the low magnification data (step S205: No), the controller 66 performs a cross determination by considering the high magnification data (step S207). The controller 66 compares an up-down direction position of the substrate S detected based on the third determination data (hereinafter referred to as a third substrate position) with an up-down direction set position of the third pole P3 corresponding to the substrate S (hereinafter referred to as a third set position). The third set position may be a common position with the first set position and/or the second set position in the up-down direction, or may be set independently of the first set position and the second set position. For example, when the third substrate position is lower than the third set position, the controller 66 determines that the accommodation state of the N^{th} substrate S is a cross state (i.e., the cross state is detected). When the cross state is detected (step S208: Yes), the controller 66 executes the above-described step S206 and terminates the determinations regarding the N^{th} substrate S.

When the cross state is not detected even though the high magnification data is taken into account (step S208: No), the controller 66 determines whether or not the substrate S is present (step S209). More specifically, the controller 66 determines whether or not the substrate S is detected in any one of the first determination region 211, the second determination region 212, and the third determination region 213 based on the determination data. When the substrate S is not detected in any one of the determination regions 210 (see FIG. 9D), the controller 66 determines that the N^{th} substrate S is not preset (step S210: No). In this case, the controller 66 stores information indicating that the N^{th} substrate S is not preset in the memory (step S211). Then, the controller 66 terminates the determinations regarding the N^{th} substrate S. When the substrate S is detected in any one of the determination regions 210, the controller 66 determines that the N^{th} substrate S is preset (i.e., is correctly stored) (step S211: No). In this case, the controller 66 terminates the determinations regarding the N^{th} substrate S as it is. In this manner, the determination process for the N^{th} substrate S is completed.

As described above, when imaging the imaging region 200, the respective cameras 61 are arranged as follows. A virtual straight line VL passing through each light receiving point RP and the detection target point SP corresponding to each light receiving point RP intersects with the non-opposing surface (the left side surface 113L or the right side surface 113R) which is a surface different from the back surface 113B of the FOUP 100. With this arrangement of the cameras 61, the imaging of the back surface 113B as a background at the detection target point SP and in the region in the vicinity thereof can be avoided as much as possible. Therefore, influence of reflected light from the back surface 113B can be suppressed as much as possible. In addition, the reflected light emitted from the lighting 62 and reflected by the non-opposing surface is suppressed from reaching the cameras 61 directly compared to the reflected light from the back surface 113B. Therefore, occurrence of erroneous determinations regarding the accommodation state of the substrate S at the detection target point SP can be avoided as much as possible. Therefore, erroneous determinations regarding the accommodation state of the substrate S can be suppressed more reliably by simple means.

Furthermore, the controller 66 uses the non-opposing surface-containing data as determination data. Therefore, data of a region of the imaging region 200 imaged using the back surface 113B as a background can be excluded from the target of the determinations performed by the controller 66. Therefore, erroneous determinations regarding the accommodation state of the substrate S can be effectively suppressed.

Furthermore, the plurality of cameras 61 (imagers) image the region of each substrate S that includes the plurality of detection target points SP. In a configuration in which determinations are required for the plurality of detection target points SP for each substrate S, if even one erroneous determination occurs, erroneous determinations will occur for all substrates S. Accordingly, the scanner part 45 of the present embodiment, which can more reliably suppress erroneous determinations, is particularly effective in this configuration.

Furthermore, a cross determination can be performed by using the first camera 63 (and the second camera 64). A double determination can be performed by using the second camera 64. Accordingly, the accommodation state of the substrate S can be determined in more detail.

Furthermore, in general, among the light reflected by the substrate S, the light reflected by the end surface SE is stronger than the light reflected by portions other than the end surface SE. Therefore, in order to more reliably detect the reflected light from the substrate S, it is preferable that the imager be configured to image at least the end surface of the substrate as in the present embodiment. In this case, the side surface (the left side surface 113L or the right side surface 113R) among the inner wall surfaces 113 of the FOUP 100 can be imaged by the cameras 61. The reflected light reflected by the side surface other than the back surface 113B and traveling directly toward the cameras 61 is significantly weaker than the reflected light travelling directly from the back surface 113B to the cameras 61. This makes it possible to effectively suppress occurrence of erroneous determinations regarding the presence or absence of the substrate S at the detection target points SP.

Next, modifications of the above-described embodiment will be described. The same components as those in the above-described embodiment will be designated by like reference numerals, and description thereof will be omitted as appropriate.

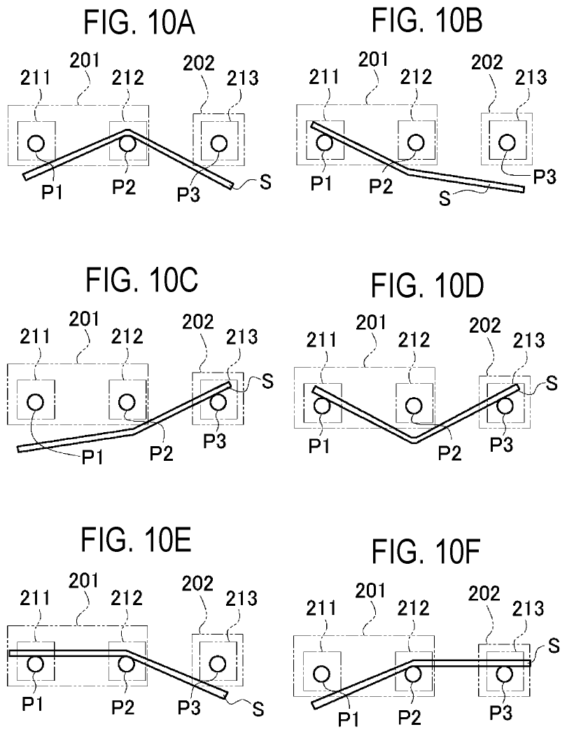

(1) The controller 66 may also be capable of determining other cross states (see FIGS. 10A to 10F) that are different from the cross state shown in the above-described embodiment. That is, the controller 66 may determine that the accommodation state of the substrate S is a cross state even in a case where the substrate S is not detected in a part (one or two) of the first determination region 211, the second determination region 212, and the third determination region 213. Such a situation is likely to occur, for example, when a substrate S which is likely to be bent for reasons such as being very thin is accommodated in the FOUP 100 and a portion of the substrate S is unintentionally arranged below the pole P, such that the portion sags significantly due to gravity.

(2) In the embodiment described above, the imaging axis of each camera 61 is assumed to be substantially horizontal, and each camera 61 is arranged to image the end surface SE of the substrate S. However, the present disclosure is not limited thereto. The camera 61 may be configured to image the substrate S from, for example, an obliquely lower and rear side or an obliquely upper and rear side. For example, in a case where the substrate S is a glass epoxy substrate, the portion near the end surface SE is slightly rounded when viewed in, for example, the left-right direction. Since such a substrate S can specularly reflect the irradiated light in various directions, there is a high probability that the substrate S can be detected even in a case where the cameras 61 are arranged as described above. When the cameras 61 are arranged to image the substrate S from the obliquely lower and rear side, the upper surface 113U is included in the non-opposing surface of the present disclosure. When the cameras 61 are arranged to image the substrate S from the obliquely upper and rear side, the lower surface 113D is included in the non-opposing surface of the present disclosure.

(3) In the embodiment described above, the plurality of cameras 61 includes the first camera 63 and the second camera 64 having different performance characteristics (for example, at least one of resolution, magnification, or field of view). However, the present disclosure is not limited thereto. The plurality of cameras 61 may include two cameras (not shown) having the same performance characteristics. One camera may perform imaging for a cross determination. The other camera or both cameras may perform imaging for a double determination. When the double determination is performed based on imaging data acquired by both cameras, it is possible to further improve an accuracy of the double determination.

(4) In the embodiment described above, the imager includes two cameras 61. However, the present disclosure is not limited thereto. The imager may include three or more cameras 61. Alternatively, the imager may include only one camera 61. In a configuration with only one camera 61, the horizontal field of view of the camera 61 may be larger than, for example, the horizontal field of view of the first camera 63. Thus, a cross detection may be performed by using a small number of cameras 61. Furthermore, the resolution of the camera 61 may be high enough to perform a double detection despite the large horizontal field of view (i.e., low magnification). Furthermore, in the embodiment described above, the imager images the region including the plurality of detection target points SP. However, the present disclosure is not limited thereto. In the configuration with only one camera 61, the camera 61 may be configured to image the region including only one detection target point SP. That is, the controller 66 may use the cameras 61 to determine, for example, only the presence or absence of the substrate S.

(5) In the embodiment described above, the controller 66 uses the non-opposing surface-containing data as the determination data. However, the present disclosure is not limited thereto. The controller 66 may also use, as the determination data, data in which the back surface 113B is slightly included as a background. Even in this case, since the virtual straight line VL intersects with the non-opposing surface, a proportion of data relating to the back surface 113B in the determination data can be effectively reduced. Accordingly, the influence of reflected light from the back surface 113B can be effectively suppressed.

(6) In the embodiment described above, one detection target point SP is set in each determination region 210. However, the present disclosure is not limited thereto. A plurality of detection target points SP may be set in each determination region 210. Alternatively, the controller 66 may be configured to detect the entire region where light is specularly reflected as a portion of the end surface SE in each determination region 210.

(7) In the embodiment described above, the front nodal point of the light receiving lens 61a of the camera 61 is defined as the light receiving point RP. However, the present disclosure is not limited thereto. The front principal point of the light receiving lens 61a, or a predetermined point on the front surface of the light receiving lens 61a, may be defined as the light receiving point RP. Alternatively, for example, in a case where the front focal point of the light receiving lens 61a is located inside the light receiving lens 61a, the front focal point may be defined as the light receiving point RP. Alternatively, the rear principal point or the rear nodal point may be defined as the light receiving point RP.

(8) The number of poles P supporting each substrate S is not limited to three. The substrate S may be supported by support members (not shown) other than the poles P. Alternatively, both ends of the substrate S in the left-right direction may be supported by support portions (not shown) formed by cutting out an inner surface of the FOUP body 101, for example. A type of container is not limited to the FOUP 100. The present disclosure can also be applied to containers (not shown), other than the FOUP 100, which has an opening, an opposing surface, and a non-opposing surface.

(9) A shape of the substrate S may be a shape other than a substantially rectangular shape when viewed in the up-down direction. The substrate S may have, for example, a substantially circular plate shape.

(10) In the embodiment described above, the scanner part 45 is fixed to, for example, the door body 50 (i.e., is driven to move in the up-down direction together with the door body 50 by the motor 58). However, the present disclosure is not limited thereto. The scanner part 45 may be configured to be capable of moving in the front-rear direction relative to the door body 50, for example. Alternatively, the scanner part 45 may be driven to move in the up-down direction independently of the door body 50 by a drive source (not shown) different from the motor 58. Alternatively, the scanner part 45 may be attached to a structure within the EFEM 1 in addition to the transfer robot 3.

(11) In the embodiment described above, the controller 66 causes each camera 61 to perform imaging based on the imaging schedule. However, the present disclosure is not limited thereto. The controller 66 may cause each camera 61 to perform imaging while determining, for example, the position of the scanner part 45 in the up-down direction. An accommodation set position of each substrate S in the up-down direction may be stored in the memory (RAM) of the controller 66 in advance, for example. The position of the scanner part 45 in the up-down direction may be determined based on the number of steps of the motor 58, which is a stepping motor, for example. When determining that the position of the scanner part 45 in the up-down direction has reached the accommodation set position of each substrate S in the up-down direction, the controller 66 may cause each camera 61 to perform imaging.

(12) In the above-described embodiment, the LP control device 46 and the controller 66 are provided separately. However, the present disclosure is not limited thereto. For example, the LP control device 46 may be equipped with the controller 66. Alternatively, instead of the controller 66, the LP control device 46 may have a function of controlling each camera 61. When the LP control device 46 has such a function, the LP control device 46 corresponds to the determiner of the present disclosure. Alternatively, for example, the control device 5 of the EFEM 1 may control the load port 4. In this case, the control device 5 corresponds to the determiner of the present disclosure.

(13) The load port 4 may be mounted on an equipment other than the EFEM 1.

(14) The present disclosure may be applied to mapping apparatuses other than the load port 4.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A mapping apparatus for detecting an accommodation state of a substrate accommodated in a container having an opening on a side surface thereof, comprising:
a light emitter configured to emit light toward at least an interior of the container; and
an imager configured to sense reflected light emitted from the light emitter and reflected toward the opening by at least the substrate and to image an imaging region including a predetermined detection target point set in advance to detect the substrate,
wherein the imager is arranged such that when imaging the imaging region, a virtual straight line passing through a predetermined light receiving point, which is determined in advance by a light receiver of the imager configured to receive the reflected light, and the detection target point intersects with a non-opposing surface, which is a surface different from an opposing surface facing the opening, among inner wall surfaces of the container.

2. The mapping apparatus of claim 1, further comprising:
a determiner configured to determine the accommodation state of the substrate by using determination information included in imaging information, which is information obtained by imaging the imaging region with the imager,
wherein the determiner uses, as the determination information, non-opposing surface-containing information which does not include region information relating to the opposing surface in the imaging region but includes region information relating to both the non-opposing surface and the detection target point in the imaging region.

3. The mapping apparatus of claim 1, wherein the detection target point includes a plurality of detection target points set in advance to detect the substrate, and
wherein the imager images a region including the plurality of detection target points.

4. The mapping apparatus of claim 2, wherein the detection target point includes a plurality of detection target points set in advance to detect the substrate, and
wherein the imager images a region including the plurality of detection target points.

5. The mapping apparatus of claim 3, wherein the imager includes:
a first camera configured to be capable of imaging a first imaging region including two or more detection target points among the plurality of detection target points; and
a second camera provided separately from the first camera and configured to be capable of imaging a second imaging region including a detection target point other than the two or more detection target points among the plurality of detection target points to detect a thickness of the substrate.

6. The mapping apparatus of claim 4, wherein the imager includes:
a first camera configured to be capable of imaging a first imaging region including two or more detection target points among the plurality of detection target points; and
a second camera provided separately from the first camera and configured to be capable of imaging a second imaging region including a detection target point other than the two or more detection target points among the plurality of detection target points to detect a thickness of the substrate.

7. The mapping apparatus of claim 1, wherein the imager is configured to be capable of imaging at least an end surface of the substrate, and
wherein the non-opposing surface is a side surface different from the opposing surface.

8. The mapping apparatus of claim 2, wherein the imager is configured to be capable of imaging at least an end surface of the substrate, and
wherein the non-opposing surface is a side surface different from the opposing surface.
